(19) United States
(12) Patent Application Publication
(10) Pub. No.: US 2023/0337385 A1
(43) Pub. Date: Oct. 19, 2023

(54) COVER PLATE FOR DISPLAY SCREEN, METHOD FOR PREPARING COVER PLATE, AND DISPLAY DEVICE

(71) Applicant: Hefei Visionox Technology Co., Ltd., Hefei (CN)

(72) Inventors: Renjie LIU, Hefei (CN); Chao Chi PENG, Hefei (CN); Shenglin LU, Hefei (CN)

(73) Assignee: Hefei Visionox Technology Co., Ltd., Hefei (CN)

(21) Appl. No.: 18/341,227

(22) Filed: Jun. 26, 2023

Related U.S. Application Data
(63) Continuation of application No. PCT/CN2021/137873, filed on Dec. 14, 2021.

(30) Foreign Application Priority Data
May 31, 2021 (CN) 202121197400.8

(51) Int. Cl. H05K 5/03; G02B 1/14

(52) U.S. Cl. CPC H05K 5/03; G02B 1/14

(57) ABSTRACT

A cover plate for a display screen, a method for preparing the cover plate, and a display device. The cover plate includes a central region and an edge region located in at least portion of a peripheral side of the central region AA, the cover plate has a thickness gradually decreasing from the central region to the edge region. The cover plate includes a plastic body and at least one first stabilizing film layer which are arranged in a stacked manner. At least one of the plastic body and the first stabilizing film layer has a thickness gradually decreasing from the central region to the edge region.

### CROSS REFERENCE TO RELATED APPLICATION

This is a Continuation Application of International Patent Application No. PCT/CN2021/137873 filed on Dec. 14, 2021, which claims the priority of Chinese Patent Application No. 202121197400.8, filed on May 31, 2021, entitled “COVER PLATE FOR DISPLAY SCREEN, METHOD FOR PREPARING COVER PLATE, AND DISPLAY DEVICE”, both of which are incorporated herein by reference in their entireties.

### TECHNICAL FIELD

This disclosure belongs to the technical field of electronic product, in particular to a cover plate for a display screen, a method for preparing the cover plate, and a display device.

### BACKGROUND

With development of smart terminal technology, screens for smart terminal are no longer limited to flat surfaces, and more manufacturers are beginning to try to use curved screens on smart terminals. Flexible display screens have the characteristics of being bendable. Using the flexibility of the display screens, the display device may be bended or folded and can thus be applied to wearable devices such as watches, thereby bringing convenience to people's wearing and using the display device. However, the hardness and dimensional stability of the cover plate of the existing flexible display screen are not sufficient to provide good protection for the display screen. Meantime, due to the limited internal space of the screen body, the internal display components are designed to be compact or small-sized, resulting in affecting the display effect.

Therefore, there is an urgent need for a novel cover plate for a display screen, a method of preparing the cover plate, and display device.

### SUMMARY

Embodiments of this disclosure provide a cover plate for a display screen, a method for preparing the cover plate, and a display device. The cover plate has the characteristics of high hardness and high dimensional stability, and has a mirror magnification effect, thereby increasing the viewing angle and improving the display effect of the display components inside the display screen.

In one aspect, an embodiment of this disclosure provides a cover plate for a display screen, including a central region and an edge region located in at least portion of a peripheral side of the central region, the cover plate having a thickness gradually decreasing from the central region to the edge region. The cover plate includes a plastic body and at least one first stabilizing film layer which are arranged in a stacked manner. At least one of the plastic body and the first stabilizing film layer has a thickness gradually decreasing from the central region to the edge region.

In some embodiments of one aspect of this disclosure, one of the plastic body and the at least one first stabilizing film layer has the thickness gradually decreasing from the central region to the edge region, and the other has a uniform thickness.

In some embodiments of one aspect of this disclosure, the plastic body has the thickness gradually decreasing from the central region to the edge region, the at least one first stabilizing film layer is provided as a multi-layer first stabilizing film layers, and each layer of the multi-layer first stabilizing film layers has a uniform thickness.

In some embodiments of one aspect of this disclosure, the plastic body has a uniform thickness, the at least one first stabilizing film layer has the thickness gradually decreasing from the central region to the edge region, the at least one first stabilizing film layer is provided as a multi-layer first stabilizing film layers, a film layer away from the plastic body among the multi-layer first stabilizing film layers has the thickness gradually decreasing from the central region to the edge region, and a film layer close to the plastic body among the multi-layer first stabilizing film layers has a uniform thickness.

In some embodiments of one aspect of this disclosure, an inner surface of the cover plate mating with a mating member is a curved surface curved at a first curvature along a first trajectory, an outer surface of the cover plate is a curved surface curved at a second curvature along a second trajectory, and the second curvature at an intersection point where a perpendicular line in a direction perpendicular to the cover plate intersects with the outer surface is greater than or equal to the first curvature at the intersection point where the perpendicular line in the direction perpendicular to the cover plate intersects with the outer surface.

In some embodiments of one aspect of this disclosure, an inner surface of the cover plate mating with a mating member is a flat surface, and an outer surface of the cover plate is a curved surface curved at a second curvature along a second trajectory.

In some embodiments of one aspect of this disclosure, in a section perpendicular to the first direction, a cross section of the cover plate has an arched surface with a thicker middle and two thinner periphery sides.

Optionally, an orthogonal projection of the cover plate in a horizontal plane is one of rectangular, elliptical, circular, quasi elliptical, and quasi circular.

In some embodiments of one aspect of this disclosure, a maximum thickness of the central region of the plastic body is in a range of 1.2 mm˜1.7 mm, and a minimum thickness of the edge region of the plastic body in a range of 0.6 mm˜1.2 mm.

In some embodiments of one aspect of this disclosure, the cover plate further includes a hardening coating, and the hardening coating is disposed on a side of the first stabilizing film layer away from the plastic body.

In some embodiments of one aspect of this disclosure, a hardness h1 of the first stabilizing film layer subjected to hardening treatment by the hardening coating, a hardness h2 of the first stabilizing film layer not subjected to hardening treatment by the hardening coating, and a hardness h3 of the plastic body satisfy a relationship of h1>h2>h3.

Optionally, a hardness h1 of the first stabilizing film layer subjected to hardening treatment by the hardening coating≥Mohs hardness 6H.

In some embodiments of one aspect of this disclosure, a maximum thickness of the first stabilizing film layer is less than a maximum thickness of the plastic body.

Optionally, the maximum thickness of the first stabilizing film layer is in a range of 0.1 mm˜0.4 mm.

In a second aspect, an embodiment of the application further provides for preparing a cover plate, the cover plate including a central region and an edge region located in at least portion of a peripheral side of the central region, the method including steps of: forming a plastic body by injection molding using a first mold; and compositing a first stabilizing film layer onto an outer surface of the plastic body by hot melting, wherein at least one of the plastic body and the first stabilizing film layer has a thickness gradually decreasing from the central region to the edge region.

Optionally, the method further includes: after the step compositing the first stabilizing film layer onto the outer surface of the plastic body by hot melting, a step of performing a hardening coating treatment to a surface of the first stabilizing film layer away from the plastic body.

In a third aspect, an embodiment of this disclosure further provides a display device, including the cover plate for the display screen as described in the above embodiments; and a display screen, wherein the cover plate is disposed on a light output side of the display screen.

Compared with the prior art, the cover plate for the display screen in the embodiment of this disclosure includes the central region and the edge region located in at least portion of a peripheral side of the central region. The thickness of the cover plate gradually decreases from the central region to the edge region, so that the outer surface of the cover plate is an arcuate surface protruding outward relative to the inner surface of the cover plate mating with a mating member, presenting as a convex lens with a thicker center and thinner peripheral sides. According to the imaging principle of convex lenses, the thickness of at least one of the plastic body and the first stabilizing film layer can be gradually decreased from the central region to the edge region in a thickness direction of the cover plate. In addition, by providing the first stabilizing film layer, the hardness and dimensional stability of the cover plate can be improved. The cover plate provided in the embodiment of this disclosure has high hardness and dimensional stability, and has a mirror magnification effect, thereby increasing the viewing angle and improving the display effect of the display components inside the display screen.

### BRIEF DESCRIPTION OF THE DRAWINGS

FIG. 1 is a structural schematic diagram of a cover plate according to an embodiment of this disclosure;

FIG. 2 is a cross-sectional view taken along a B-B direction in an embodiment of FIG. 1;

FIG. 3 is a structural schematic diagram of a cover plate according to another embodiment of this disclosure;

FIG. 4 is a cross-sectional view taken along a B-B direction in another embodiment of FIG. 1;

FIG. 5 is a flowchart of a method for preparing a cover plate according to an embodiment of this disclosure;

FIG. 6 is a schematic diagram of the preparation of a plastic body in an embodiment of this disclosure;

FIG. 7 is a schematic diagram of the preparation of a first stabilizing film layer covering an outer surface of a plastic body in an embodiment of this disclosure;

FIG. 8 is a schematic diagram of the preparation of a cover plate in an embodiment of this disclosure.

### DETAILED DESCRIPTION

Below, features and exemplary embodiments of various aspects of this disclosure will be described in detail. In the following detailed description, many specific details are proposed to provide a comprehensive understanding of this disclosure. However, it is apparent to those skilled in the art that this disclosure may be implemented without some of these specific details. The description of the embodiments below is only intended to provide a better understanding of this disclosure by showing examples of this disclosure.

In order to better understand this disclosure, a cover plate for a display screen, a method for preparing the cover plate, and a display device according to embodiments of this disclosure will be described in detail in conjunction with FIGS. 1 to 8.

Please refer to FIGS. 1 to 8, an embodiment of this disclosure provides a cover plate 100 for a display screen. The cover plate 100 includes a central region AA and an edge region PA located in at least portion of a peripheral side of the central region AA. The cover plate 100 has a thickness gradually decreasing from the central region AA to the edge region PA, and the cover plate 100 includes a plastic body 1 and at least one first stabilizing film layer 2 which are arranged in a stacked manner. At least one of the plastic body 1 and the first stabilizing film layer 2 has a thickness gradually decreasing from the central region AA to the edge region PA.

The cover plate 100 for the display screen in the embodiment of this disclosure includes the central region AA and the edge region PA located in at least portion of the peripheral side of the central region AA, and the thickness of the cover plate 100 gradually decreases from the central region AA to the edge region PA, so that an outer surface of the cover plate 100 is an arcuate surface protruding outward relative to an inner surface of the cover plate 100 mating with a mating member, presenting as a convex lens with a thicker center and thinner peripheral sides. According to the imaging principle of the convex lens, the thickness of at least one of the plastic body 1 and the first stabilizing film layer 2 may be gradually decreased from the central region AA to the edge region PA in a thickness direction of the cover plate 100. In addition, by providing the first stabilizing film layer 2, the hardness and dimensional stability of the cover plate 100 can be improved. The cover plate 100 provided in the embodiment of this disclosure has high hardness and dimensional stability, and has a mirror magnification effect, thereby increasing the viewing angle and improving the display effect of the display components inside the display screen.

The cover plate 100 for the display screen in the embodiment of this disclosure includes the central region AA and the edge region PA located in at least portion of the peripheral side of the central region AA. The edge region PA located in at least portion of the peripheral side of the central region AA may refer to either the edge regions on two sides of the central region as shown in FIG. 1 or the edge regions on a circumferential side around the central region as shown in FIG. 3.

In order to ensure the hardness and dimensional stability of the cover plate 100, the cover plate 100 includes the plastic body 1 and at least one first stabilizing film layer 2 which are arranged in a stacked manner. The plastic body 1 includes an inner surface 11 and an outer surface 12 opposite to each other. The inner surface 11 of the plastic body 1 is mating with a mating member, and the first stabilizing film layer 2 is disposed to at least partially cover the outer surface 12 of the plastic body 1, thereby the cover plate 100 is formed with the plastic body 1 as the inner surface and the first stabilizing film layer 2 as the outer surface. By disposing the plastic body 1 with good dimensional stability as the inner surface of the cover plate 100 and disposing the first stabilizing film layer 2 with high hardness as the outer surface of the cover plate 100, the cover plate 100 can have good dimensional stability as well as good hardness, to meet the use requirements of wearable devices. According to the actual hardness requirements for the cover plate 100, the first stabilizing film layer 2 may be provided with one or more layers.

In order to enable the thickness of the cover plate 100 to be gradually decreased from the central region AA to the edge region PA, the thickness of at least one of the plastic body 1 and the first stabilizing film layer 2 may be disposed to be gradually decreased from the central region AA to the edge region PA in the thickness direction of the cover plate 100, thereby causing the overall film thickness of the plastic body 1 and the first stabilizing film layer 2 which are arranged in a stacked manner to be gradually decreased from the central region AA to the edge region PA.

The thickness of at least one of the plastic body 1 and the first stabilizing film layer 2 gradually decreasing from the central region AA to the edge region PA in the thickness direction of the cover plate 100 means that each of the plastic body 1 and the first stabilizing film layer 2 has the thickness gradually decreasing from the central region AA to the edge region PA.

Alternatively, it means that one of the plastic body 1 and the first stabilizing film layer 2 has the thickness gradually decreasing from the central region AA to the edge region PA while the other has a uniform thickness. Specifically, the plastic body 1 has the thickness gradually decreasing from the central region AA to the edge region PA while the at least one the first stabilizing film layer 2 has a uniform thickness; and if at least one the first stabilizing film layer is provided as a multi-layer first stabilizing film layers, each layer of the multi-layer first stabilizing film layers has a uniform thickness. Alternatively, the plastic body 1 has a uniform thickness while at least one the first stabilizing film layer 2 has the thickness gradually decreasing from the central region AA to the edge region PA; and if at least one the first stabilizing film layer is provided as a multi-layer first stabilizing film layers, a film layer away from the plastic body among the multi-layer first stabilizing film layers has the thickness gradually decreasing from the central region to the edge region, a film layer close to the plastic body among the multi-layer first stabilizing film layers has a uniform thickness, and other film layers among the multi-layer first stabilizing film layers has a uniform thickness. Preferably, the first stabilizing film layer in contact with the plastic body among the multi-layer first stabilizing film layers is a film layer with uniform thickness.

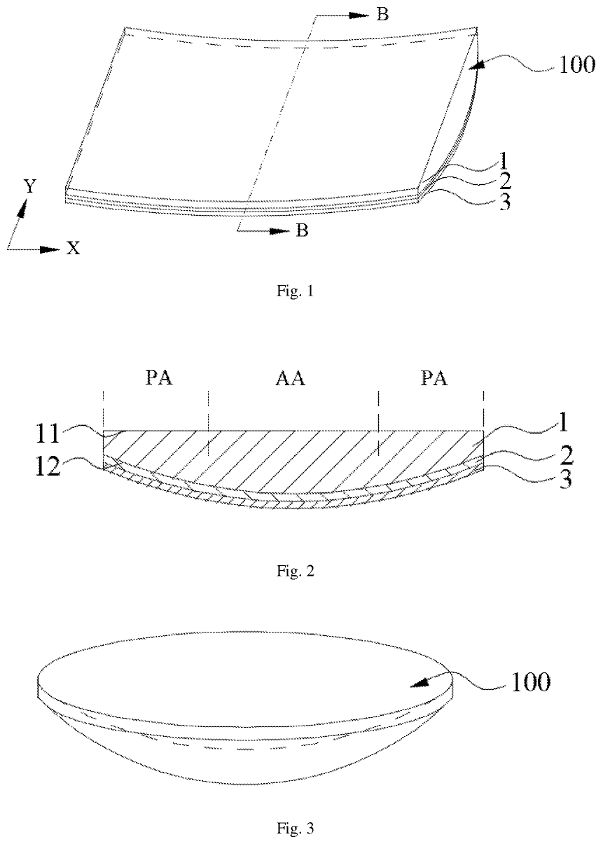

Please refer to FIGS. 1 and 2, for ease of description, an example in which the plastic body 1 has the thickness gradually decreasing from the central region AA to the edge region PA and the first stabilizing film layer 2 has a uniform thickness is illustrated. If the transverse extending direction of plastic body 1 is defined as a first direction X and the longitudinal extending direction is defined as a second direction Y, the central region AA of plastic body 1 refers to a region portion that spreads along the second direction Y with a centerline of plastic body 1 in the first direction X as a reference, and the edge region PA refers to regions adjacent to the central region AA on two sides of the central region AA. It should be stated that the thickness of the cover plate 100 and the thickness of the plastic body 1 and the first stabilizing film layer 2 of the cover plate 100 specifically refers to the length of the plastic body 1 and the first stabilizing film layer 2 in a direction perpendicular to the first direction X.

It should be stated, since the thickness of plastic body 1 gradually decreases from the central region AA to the edge region PA, the outer surface 12 is formed as an arcuate surface protruding outward relative to the inner surface 11. The plastic body 1 gradually thins and transitions in an arc from the center area AA to the edge area PA in the second direction Y with the centerline of plastic body 1 in the first direction X as a reference, presenting as a convex lens with a thicker center and two thinner periphery sides. Therefore, when the user views the display screen from the outer surface 12 of the plastic body 1 toward the inner surface 11, the convex lens will amplify the display components inside the display screen according to refraction principle of light, thereby achieving the effect of increasing the viewing angle of the cover plate 100.

According to the imaging principle of convex lenses, the thickness of the central region AA of the cover plate 100 and the distance between the central region AA and the components inside the display screen may affect the mirror magnification ratio of the cover plate 100. Therefore, by adjusting the dimensional structure of the inner and outer surfaces of the cover plate 100, the display effect of the display screen can be improved.

Please refer to FIGS. 1 and 2, the inner surface of the cover plate 100 mating with a mating member is a curved surface curved at a first curvature along a first trajectory, and the outer surface 12 of the cover plate 100 is a curved surface curved at a second curvature along a second trajectory. The second curvature at an intersection point where a perpendicular line in a direction perpendicular to the cover plate intersects with the outer surface is greater than or equal to the first curvature at the intersection point where the perpendicular line in the direction perpendicular to the cover plate intersects with the outer surface. The curvature of the inner surface along the first direction X in a longitudinal section is the first curvature, and the curvature of the outer surface along the first direction X in the longitudinal section is the second curvature. Considering that the outer profile of existing wearable devices is disposed as a curved surface, the cover plate 100 can be applied to various displays by disposing its outer surface as a curved surface.

According to the refraction principle of light, in order to ensure the true imaging of the display components inside the cover plate 100, the second curvature at the intersection point where the perpendicular line in the direction perpendicular to the cover plate intersects with the outer surface may be disposed to be greater than or equal to the first curvature at the intersection point where the perpendicular line in the direction perpendicular to the cover plate intersects with the outer surface, to ensure that the imaging is not distorted after the light is refracted between the inner and outer surfaces. The specific values of the second curvature and the first curvature, as well as the difference between the first and second curvatures, may be adjusted according to actual situations, and are not specifically limited here. In addition or alternatively, in order to facilitate the production of the cover plate 100, the inner surface of the cover plate may be flat, and the outer surface may be disposed as a curved surface curved at the second curvature along the trajectory extending in the first direction X, thus a flat-convex lens may be formed. Specifically, the outer surface is formed as an outward convex surface that protrudes in a direction away from the inner surface relative to the inner surface, thereby a flat-convex lens or a convex lens is formed. Compared to the convex lens, the flat-convex lens can provide more reliable protection for components inside the display screen and can be more easily applied into wearable devices.

It can be understood that when the first stabilizing film layer 2 has a uniform thickness, the inner surface 11 of the plastic body 1 may be disposed as a curved surface curved at the first curvature along the first trajectory or a flat surface, and the outer surface 12 may be disposed as a curved surface curved at the second curvature along the second trajectory, to achieve curvature adjustment of the inner and outer surfaces of the cover plate 100.

Please refer to FIGS. 1 and 3, specifically, in a section perpendicular to the first direction X, i.e., in a section where the thickness direction of the cover plate is located, a cross section of the cover plate has an arched surface with a thicker middle and two thinner periphery sides. The radians of the surfaces on both sides of the arched surface are specifically determined by the curvatures of the surfaces of the plastic body 1 and the first stabilizing film layer 2. The specific shape of the cover plate 100 may be adjusted according to the needs of the display device. As long as the thickness of the cover plate gradually decreasing from the central region AA to the edge region PA can be ensured, the specific shape thereof is not limited here. Specifically, the outer contour line of the cover plate 100 may be a straight line or a curve, that is, when the cross section of the cover plate has an arched surface with a thicker middle and two thinner periphery sides, an orthogonal projection of the cover plate 100 in a horizontal plane may be one of rectangular, elliptical, circular, quasi elliptical, and quasi circular. By adjusting the shape of the cover plate 100, the cover plate 100 can be applied to displays of different sizes and shapes, to meet the needs of different types of display devices.

In the embodiment of this disclosure, a maximum thickness of the central region AA of the plastic body 1 is in a range of 1.2 mm˜1.7 mm, and a minimum thickness of the edge region PA of the plastic body 1 is in a range of 0.6 mm˜1.2 mm. On one hand, in order to ensure the magnification imaging effect of the cover plate 100, the thickness of the central region AA should be greater than the thickness of the edge region PA. On the other hand, in order to ensure the hardness and dimensional stability of the cover plate 100 as a whole, the minimum thickness of the edge region PA should not be too small. Therefore, the thickness of the central region AA and the edge region PA may be adjusted according to actual situations, as long as the design requirements can be satisfied while a smooth transition between the central region AA and the edge region PA can be ensured.

Further, a maximum thickness of the first stabilizing film layer 2 disposed on a side of the outer surface 12 of the plastic body 1 is less than a maximum thickness of the plastic body 1. By controlling the thickness of the first stabilizing film layer 2, it is easy to achieve ultra-thinning of the cover plate 100 while avoiding the display effect of the display device being affected by the first stabilizing film layer 2 being too thick. Optionally, the maximum thickness of the first stabilizing film layer 2 is in a range of 0.1 mm˜0.4 mm, thereby effectively ensuring the overall hardness and dimensional stability of the cover plate 100.

Please refer to FIGS. 1 and 2, in order to improve the hardness and stability of the cover plate 100, the cover plate further includes a hardening coating 3, which is located on a side of the first stabilizing film layer 2 away from the plastic body 1. By performing hardening coating treatment to the side of the cover plate 100 away from the display components inside the display screen to form the hardening coating 3, the hardness of the cover plate 100 can be further enhanced, ensuring the safety of the display device and improving the service life of the display screen.

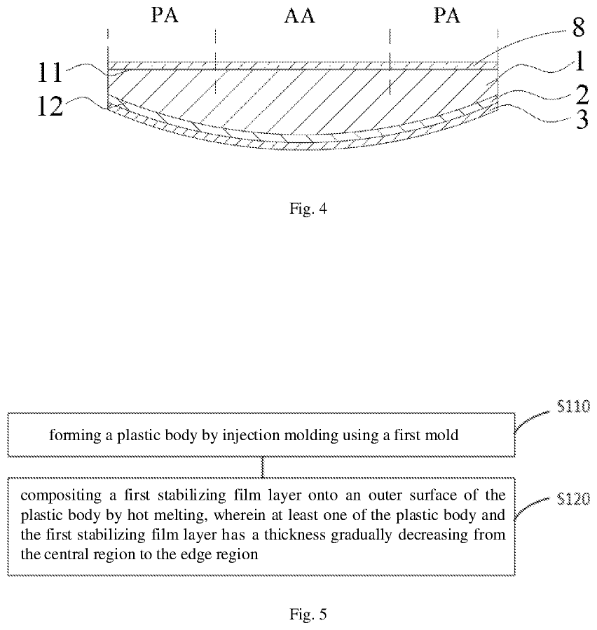

Please refer to FIG. 4, in order to further improve the hardness and stability of the cover plate, the cover plate 100 further includes a second stabilizing film layer 8, which is disposed to cover the inner surface 11 of the plastic body 1. The second stabilizing film layer 8 may be provided with the same material as the first stabilizing film layer 2, that is, the respective stabilizing film layer is provided on each of the inner and outer sides of the plastic body 1. By providing the second stabilizing film layer 8 on the inner surface 11 of the plastic body 1, the safety of the inner side of the plastic body 1 can be ensured, and the collision and damage to the inner surface 11 of the plastic body 1 caused by the movement of the display components inside the display screen can be avoided.

In the embodiment of this disclosure, in order to ensure that the hardness of the cover plate 100 satisfies the requirements, a hardness h1 of the first stabilizing film layer 2 subjected to hardening treatment by the hardening coating 3, a hardness h2 of the first stabilizing film layer 2 not subjected to hardening treatment by the hardening coating 3, and a hardness h3 of the plastic body 1 satisfy a relationship of h1>h2>h3, thereby ensuring that the hardness of the cover plate 100 can be enhanced after the plastic body 1 is covered by the first stabilizing film layer 2.

It should be stated that the first stabilizing film layer 2 subjected to hardening treatment by the hardening coating 3 specifically refers to the first stabilizing film layer 2 coating with the hardening coating 3. The first stabilizing film layer 2 subjected to hardening treatment has a higher hardness.

Optionally, the hardness h1 of the first stabilizing film layer 2 subjected to hardening treatment by the hardening coating 3≥Mohs hardness 6H. The material of the plastic body 1 may be provided from polycarbonate (PC), which has certain light transmittance and flexibility. By utilizing the flexibility characteristics of organic material, the flexibility of the cover plate can be improved, allowing the plastic body 1 to release some external forces through deformation under external impact, reducing the impact of external forces on the cover plate 100. The first stabilizing film layer 2 includes one or more of polyimide layer (PI), polyethylene layer (PE) and polymethyl methacrylate layer (PMMA), wherein PMMA material has high transparency. Therefore, by providing the plastic body 1 made of PC material with high dimensional stability and good toughness as the inner layer of the cover plate 100 and the first stabilizing film layer 2 made of PMMA material with high hardness as the outer layer of the cover plate 100, the cover plate 100 can have the advantages of high dimensional stability and high hardness, thereby meeting the use requirements of wearable devices and increasing the service life.

In addition, the hardening coating 3 may be provided as a hard coat (HC) film, and HC film is a film in which, a film like material or a film substrate, made of curing hardening coating materials, has undergone hard coating treatment on both sides. By performing HC spray coating treatment to the side of the first stabilizing film layer 2 away from the plastic body 1, the hardness of the cover plate 100 can be significantly increased, and the surface hardness of the cover plate 100 can be stabilized to a Mohs hardness above 6H.

Please refer to FIGS. 5 to 8, this disclosure also provides a method for preparing a cover plate, wherein the cover plate 100 includes a central region AA and an edge region PA located in at least portion of a peripheral side of the central region AA. The method for preparing the cover plate includes:
S110: forming the plastic body 1 by injection molding using a first mold 4; and
S120: compositing the first stabilizing film layer 2 onto the outer surface 12 of the plastic body 1 by hot melting, wherein at least one of the plastic body 1 and the first stabilizing film layer 2 has a thickness gradually decreasing from the central region AA to the edge region PA.

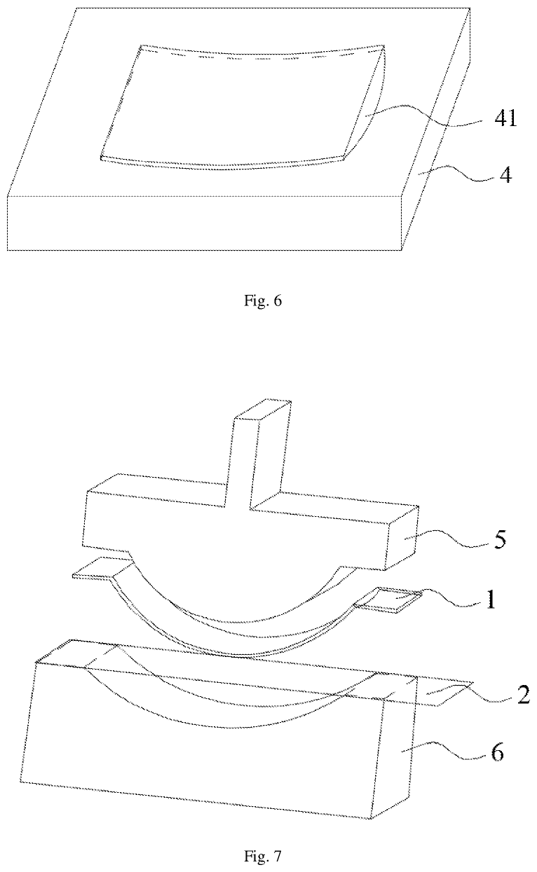

Please refer to FIG. 6, in the step S110, the first mold 4 includes a first groove 41, which corresponds to the plastic body 1 in terms of shape and size. The plastic body 1 may be formed by injection molding using the first mold 4. The depression degree of the first groove 41 gradually decreases from the central region AA to the edge region PA, resulting in the thickness of the plastic body 1 formed by injection molding gradually decreasing from the central region AA to the edge region PA, thereby achieving a display effect with mirror magnification. The injection molding material may be selected from PC material, to ensure good dimensional stability and toughness while improving light transmittance.

Refer to FIG. 7, in the step S120, the first stabilizing film 2 is composited onto the outer surface 12 of the plastic body 1 by hot melting, so that the cover plate 100 has good dimensional stability as well as good strength and toughness. In order to ensure that the first stabilizing film 2 can be stably disposed onto the outer surface 12 of the plastic body 1, the second mold 5 and the third mold 6 may be provided in a stacked manner. By stacking the plastic body 1 and the first stabilizing film layer 2 between the second mold 5 and the third mold 6, and by disposing the first stabilizing film layer 2 onto the outer surface 12 of the plastic body 1, and by pressing the second mold 5 tightly against the third mold 6 by hot melting, the first stabilizing film layer 2 can be stably composited onto the outer surface 12 of the plastic body 1.

Specifically, since the inner surface 11 of the plastic body 1 is formed as a curved surface curved at the first curvature and the outer surface 12 is formed as a curved surface curved at the second curvature, the second mold 5 may be provided to be convex at the first curvature and the third mold 6 may be provided to be concave at the second curvature. By abutting the convex portion of the second mold 5 against the inner surface 11 of the plastic body 1, by abutting the concave portion of the third mold 6 against the outer surface of the first stabilizing film layer 2, and by pressing the second mold 5 tightly against the third mold 6, the first stabilizing film layer 2 can be stably composited onto the outer surface 12 of the plastic body 1.

Furthermore, after the step S120, the surface of the first stabilizing film layer 2 away from the plastic body 1 may be subjected to HC coating treatment. The HC coating may be made by curing a nano hard coating. Specifically, the nano hard coating may be coated onto the surface of the first stabilizing film layer 2 away from the plastic body 1 using a micro concave coating roller or by spraying, after the nano hard coating is cured onto a film, the hardening coating 3 can be formed, thereby the hardness of the cover plate 100 can be further improved.

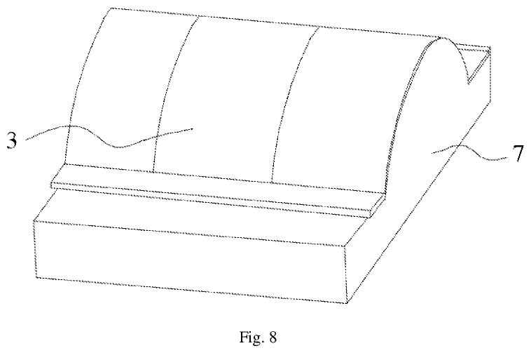

Please refer to FIG. 8, after the surface of the first stabilizing film layer 2 away from the plastic body 1 is subjected to HC coating treatment, excess material is removed through computerized numerical control (CNC) machining on the fourth mold 7, ultimately achieving the formation of the cover plate 100. In order to ensure that the first stabilizing film layer 2 can fully cover the outer surface 12 of the plastic body 1, the area of the first stabilizing film layer 2 is disposed to be larger than that of the outer surface 12 of the plastic body 1. Therefore, after compositing the first stabilizing film layer 2 onto the plastic body 1, it is necessary to remove the excess material. In addition, the shape of the corners of the cover plate 100 may also be trimmed to achieve the final formation of the cover plate 100.

An embodiment of this disclosure also provides a display device including the cover plate 100 and a display screen. The cover plate is the cover plate 100 for the display screen in the above embodiments, and the cover plate 100 is disposed on a light output side of the display screen. On one hand, it is possible to ensure the safety of various components inside the display screen, and on the other hand, it can play a mirror magnifying role in the display components inside the display screen, increasing the viewing angle.

The display device provided in the embodiment of this disclosure has the technical effect achieved by the cover plate for the display screen in any of the above embodiments. The same or corresponding structure and terminology explanation as the above embodiments will not be repeated here. The display device provided in the embodiments of this disclosure may be a wearable device or any electronic product having display functions, including but not limited to the following categories: television, laptop, desktop display, tablet, digital camera, smart bracelet, smart glasses, car mounted display, medical equipment, industrial control equipment, touch interaction terminal, etc. This is not limited in the embodiment of this disclosure.

The above description is only illustrated as the specific implementation of this disclosure, and it can be apparently understood by those skilled in the art that for the convenience and conciseness of the description, the specific working process of the system, module, and unit described as above may refer to the corresponding process in the aforementioned method implementation, and will not be repeated here. It should be understood that the protection scope of this disclosure is not limited hereto. Various equivalent modifications or replacements can be easily conceived by those skilled in the art within the technical scope of this disclosure and should be covered within the protection scope of this disclosure.

It should also be stated that the exemplary embodiments mentioned in this disclosure describe some methods or systems based on a series of steps or devices. However, this disclosure is not limited to the order of the steps mentioned as above. In other words, the steps may be executed according to the order mentioned in the embodiments, or according to the order different from that in the embodiments, or a plurality of steps may be executed simultaneously.

What is claimed is:

1. A cover plate for a display screen, comprising a central region and an edge region located in at least portion of a peripheral side of the central region, the cover plate having a thickness gradually decreasing from the central region to the edge region;
the cover plate comprising a plastic body and at least one first stabilizing film layer which are arranged in a stacked manner; and
at least one of the plastic body and the first stabilizing film layer having a thickness gradually decreasing from the central region to the edge region.

2. The cover plate for the display screen as claimed in claim 1, wherein one of the plastic body and the at least one first stabilizing film layer has the thickness gradually decreasing from the central region to the edge region, and the other has a uniform thickness.

3. The cover plate for the display screen as claimed in claim 2, wherein the plastic body has the thickness gradually decreasing from the central region to the edge region, and the at least one first stabilizing film layer has a uniform thickness.

4. The cover plate for the display screen as claimed in claim 3, wherein the at least one first stabilizing film layer is provided as a multi-layer first stabilizing film layers, and each layer of the multi-layer first stabilizing film layers has a uniform thickness.

5. The cover plate for the display screen as claimed in claim 2, wherein the plastic body has a uniform thickness, the at least one first stabilizing film layer has the thickness gradually decreasing from the central region to the edge region, the at least one first stabilizing film layer is provided as a multi-layer first stabilizing film layers, a film layer away from the plastic body among the multi-layer first stabilizing film layers has the thickness gradually decreasing from the central region to the edge region, and a film layer close to the plastic body among the multi-layer first stabilizing film layers has a uniform thickness.

6. The cover plate for the display screen as claimed in claim 1, wherein an inner surface of the cover plate mating with a mating member is a curved surface curved at a first curvature along a first trajectory, an outer surface of the cover plate is a curved surface curved at a second curvature along a second trajectory, and the second curvature at an intersection point where a perpendicular line in a direction perpendicular to the cover plate intersects with the outer surface is greater than or equal to the first curvature at the intersection point where the perpendicular line in the direction perpendicular to the cover plate intersects with the outer surface.

7. The cover plate for the display screen as claimed in claim 1, wherein an inner surface of the cover plate mating with a mating member is a flat surface, and an outer surface of the cover plate is a curved surface curved at a second curvature along a second trajectory.

8. The cover plate for the display screen as claimed in claim 6, wherein in a section perpendicular to the first direction, a cross section of the cover plate has an arched surface with a thicker middle and two thinner periphery sides.

9. The cover plate for the display screen as claimed in claim 8, wherein an orthogonal projection of the cover plate in a horizontal plane is one of rectangular, elliptical, circular, quasi elliptical, and quasi circular.

10. The cover plate for the display screen as claimed in claim 1, wherein a maximum thickness of the central region of the plastic body is in a range of 1.2 mm˜1.7 mm, and a minimum thickness of the edge region of the plastic body is in a range of 0.6 mm˜1.2 mm.

11. The cover plate for the display screen as claimed in claim 1, further comprising a hardening coating, and the hardening coating is disposed on a side of the first stabilizing film layer away from the plastic body.

12. The cover plate for the display screen as claimed in claim 11, wherein a hardness h1 of the first stabilizing film layer subjected to hardening treatment by the hardening coating, a hardness h2 of the first stabilizing film layer not subjected to hardening treatment by the hardening coating, and a hardness h3 of the plastic body satisfy a relationship of h1>h2>h3.

13. The cover plate for the display screen as claimed in claim 12, wherein the hardness h1 of the first stabilizing film layer subjected to hardening treatment by the hardening coating≥Mohs hardness 6H.

14. The cover plate for the display screen as claimed in claim 1, wherein a maximum thickness of the first stabilizing film layer is less than a maximum thickness of the plastic body.

15. The cover plate for the display screen as claimed in claim 14, wherein the maximum thickness of the first stabilizing film layer is in a range of 0.1 mm˜0.4 mm.

16. A method for preparing a cover plate, the cover plate comprising a central region and an edge region located in at least portion of a peripheral side of the central region, the method comprising steps of:
forming a plastic body by injection molding using a first mold; and
compositing a first stabilizing film layer onto an outer surface of the plastic body by hot melting, wherein at least one of the plastic body and the first stabilizing film layer has a thickness gradually decreasing from the central region to the edge region.

17. The method for preparing the cover plate as claimed in claim 16, further comprises: after compositing the first stabilizing film layer onto the outer surface of the plastic body by hot melting, a step of:
performing a hardening coating treatment to a surface of the first stabilizing film layer away from the plastic body.

18. A display device, comprising:
the cover plate for the display screen as claimed in claim 1; and
a display screen, wherein the cover plate is disposed on a light output side of the display screen.
